(19) United States
(12) Patent Application Publication
(10) Pub. No.: US 2003/0107137 A1
(43) Pub. Date: Jun. 12, 2003

(54) Micromechanical device contact terminals free of particle generation

(76) Inventors: Roger J. Stierman, Dallas, TX (US); Seth Miller, Sachse, TX (US); Howard R. Test, Plano, TX (US); Christo P. Bojkov, Plano, TX (US); John P. Harris, Whitewright, TX (US); Reynaldo M. Rincon, Richardson, TX (US); Scott W. Mitchell, Plano, TX (US); Gonzalo Amador, Dallas, TX (US)

Correspondence Address: TEXAS INSTRUMENTS INCORPORATED, P O BOX 655474, M/S 3999, DALLAS, TX, 75265

(21) Appl. No.: 09/963,066

(22) Filed: Sep. 24, 2001

(51) Int. Cl. H01L 23/48; H01L 23/52; H01L 29/40

(52) U.S. Cl. 257/763

(57) ABSTRACT

A microelectronic mechanical structure (MEMS) comprising a semiconductor chip having an integrated circuit including a plurality of micromechanical components, and a plurality of conductive routing lines integral with the chip; the routing lines having contact terminals of oxide-free metal; and the terminals having a layer of barrier metal on the oxide-free metal and an outermost layer of noble metal, whereby damage-free testing of the circuit is possible using test probe needles.

The barrier metal is selected from a group consisting of nickel, cobalt, chromium, molybdenum, titanium, tungsten, tantalum, palladium, platinum, rhodium, rhenium, osmium, vanadium, iron, ruthenium, niobium, iridium, zirconium, hafnium, copper, and alloys thereof. Alloys of these metals may contain phosphorus or boron.

The outermost layer is a noble metal which is bondable or solderable, and is selected from a group consisting of gold, platinum, palladium, silver, rhodium, and copper. Alloys of these metals may contain phosphorus or boron.

### FIELD OF THE INVENTION

The present invention is related in general to the field of semiconductor devices and processes and more specifically to the structure and process for depositing metal layers on micromechanical device contact pads so that no metal particles are generated at multiprobing.

### DESCRIPTION OF THE RELATED ART

Micromechanical devices include actuators, motors, sensors, spatial light modulators (SLM), digital micromirror devices or deformable mirror devices (DMD), and others. The technical potential of these devices is especially evident when the devices are integrated with semiconductor circuitry using the miniaturization capability of semiconductor technology.

SLMs are transducers that modulate incident light in a special pattern pursuant to an electrical or other input. The incident light may be modulated in phase, intensity, polarization or direction. SLMs of the deformable mirror class include micromechanical arrays of electronically addressable mirror elements or pixels, which are selectively movable or deformable. Each mirror element is movable in response to an electrical input to an integrated addressing circuit formed monolithically with the addressable mirror elements in a common substrate. Incident light is modulated in direction and/or phase by reflection from each element.

As set forth in greater detail in commonly assigned U.S. Pat. No. 5,061,049, issued on Oct. 29, 1991 (Hornbeck, “Spatial Light Modulator and Method”), deformable mirror SLMs are often referred to as DMDs in three general categories: elastometric, membrane, and beam. The latter category includes torsion beam DMDs, cantilever beam DMDs, and flexure beam DMDs. Each movable mirror element of all three types of beam DMD includes a relatively thick metal reflector supported in a normal, undeflected position by an integral, relatively thin metal beam. In the normal position, the reflector is spaced from a substrate-supported, underlying control electrode, which may have a voltage selectively impressed thereon by the addressing circuit.

When the control electrode carries an appropriate voltage, the reflector is electrostatically attracted thereto and moves or is deflected out of the normal position toward the control electrode and the substrate. Such movement or deflection of the reflector causes deformation of its supporting beam storing therein potential energy which tends to return the reflector to its normal position when the control electrode is de-energized. The deformation of a cantilever beam comprises bending about an axis normal to the beam's axis. The deformation of a torsion beam comprises deformation by twisting about an axis parallel to the beam's axis. The deformation of a flexure beam, which is a relatively long cantilever beam connected to the reflector by a relatively short torsion beam, comprises both types of deformation, permitting the reflector to move in piston-like fashion.

A typical DMD includes an array of numerous pixels, the reflectors of each of which are selectively positioned to reflect or not to reflect light to a desired site. In order to avoid an accidental engagement of a reflector and its control electrode, a landing electrode may be added for each reflector. It has been found, though, that a deflected reflector will sometimes stick or adhere to its landing electrode. It has been postulated that such sticking is caused by intermolecular attraction between the reflector and the landing electrode or by high surface energy substances adsorbed on the surface of the landing electrode and/or on the portion of the reflector which contacts the landing electrode. Substances which may impart such high surface energy to the reflector-landing electrode interface include water vapor or other ambient gases (e.g., carbon monoxide, carbon dioxide, oxygen, nitrogen), gases and organic components resulting from or left behind following production of the DMD, and particulate contamination. A suitable DMD package is disclosed in commonly assigned U.S. Pat. No. 5,293,511 issued on Mar. 8, 1994 (Poradish et al., “Package for a Semiconductor Device”).

A dominant source of particulate contamination are the loose aluminum particles, which are freed and airborne by indenting and scratching actions of the aluminum bond pads in the multiprobe testing process involving tungsten needles.

The described sensitivity of most micromechanical devices would make it most desirable to protect them against dust, particles, gases, moisture and other environmental influences during all process steps involved in device assembly and packaging. It is, therefore, especially unfortunate that conventional assembly using gold wire bonding does not permit the removal of any protective material from the micromechanical devices after wire bonding completion, so that the devices have to stay unprotected through these process steps. As a consequence, yield loss is almost unavoidable.

An urgent need has therefore arisen for a coherent, low-cost method of avoiding the generation of particulate contamination at the point of origin. The method should be flexible enough to be applied for different micromechanical product families and a wide spectrum of design and process variations. Preferably, these innovations should be accomplished while increasing throughput and without lengthening the production cycle time.

### SUMMARY OF THE INVENTION

The present invention discloses a micromechanical device comprising a semiconductor chip having an integrated circuit including a plurality of micromechanical components, and a plurality of conductive routing lines integral with the chip; the routing lines having contact terminals of oxide-free metal; and the terminals having a layer of barrier metal on the oxide-free metal and an outermost layer of noble metal, whereby damage-free testing of the circuit is possible using test probe needles.

Due to the damage-free testing operation, no loose particles are generated by the test needles (“probe card”), and particulate contamination of the micromechanical components is avoided. Contact terminals conventionally having aluminum as the top metal receive a barrier metal layer and a noble metal layer on the aluminum according to the invention. These terminals are then immune to scratches by probe needle tips and thus no longer generate aluminum particles.

The barrier metal is selected from a group consisting of nickel, cobalt, chromium, molybdenum, titanium, tungsten, tantalum, palladium, platinum, rhodium, rhenium, osmium, vanadium, iron, ruthenium, niobium, iridium, zirconium, hafnium, copper, and alloys thereof. Alloys of these metals may contain phosphorus or boron.

The outermost layer is a noble metal which is bondable or solderable, and is selected from a group consisting of gold, platinum, palladium, silver, rhodium, and copper. Alloys of these metals may contain phosphorus or boron.

It is an aspect of the present invention to be applicable to a variety of different semiconductor micromechanical devices, for instance actuators, motors, sensors, spatial light modulators, and deformable mirror devices. In all applications, the invention achieves technical advantages as well as significant cost reduction and yield increase.

In a key embodiment of the invention, the micromechanical components are micromirrors for a digital mirror device. In this case, the terminals are either aluminum or copper, and the metals layers of the invention eliminate the aluminum particulate contamination of known technology, resulting in significantly higher assembly and process yield and enhanced device quality and reliability.

Another aspect of the invention is to provide terminals suitable for wire bonding or gor solder ball attachment.

Another aspect of the invention is a wide range of deposition methods available to fabricate the metal layers: Electroless plating; chemical vapor deposition; sputtering; evaporating. The most cost-effective method can be selected based on specific assembly (for instance, temperature) and packaging requirements.

The technical advances represented by the invention, as well as the aspects thereof, will become apparent from the following description of the preferred embodiments of the invention, when considered in conjunction with the accompanying drawings and the novel features set forth in the appended claims.

### BRIEF DESCRIPTION OF THE DRAWINGS

FIG. 1 is a schematic cross section of an IC bond pad with a two-layer metal cap according to the first embodiment of the invention.

FIG. 1A illustrates a cap of two stacked metal layers over the bond pad IC metallization.

FIG. 1B illustrates the bond pad of FIG. 1A including a ball-bonded wire.

FIG. 2 is a schematic cross section of an IC bond pad with a three-layer metal cap according to the second embodiment of the invention.

FIG. 2A illustrates a cap of three stacked metal layers over the bond pad IC metallization.

FIG. 2B illustrates the bond pad of FIG. 2A including a ball-bonded wire.

FIG. 3 is a microphotograph of a conventional aluminum bond pad showing the severe damage inflicted, and large particles generated, by 5 consecutive touchdowns of a tungsten-rhenium needle in the course of IC testing.

FIG. 4 is a microphotograph of an aluminum bond pad protected by the metal cap according to the invention showing the minimal damage inflicted, and no particles generated, by 20 consecutive touchdowns of a tungsten-rhenium needle in the course of IC testing.

FIG. 5 illustrates a block diagram of the process flow for fabricating the bond pad cap of an MEMS according to the second embodiment of the invention.

### DETAILED DESCRIPTION OF THE PREFERRED EMBODIMENTS

The present invention is related to U.S. patent application Ser. No. 09/775,322, filed Feb. 1, 2001 (Stierman et al., “Structure and Method for Bond Pads of Copper Metallized Integrated Circuits”).

FIG. 1A shows a schematic cross section of a first embodiment of the invention, generally designated 100. An integrated circuit (IC) has interconnecting metallization and is covered by a moisture-impenetrable protective overcoat 101. In DMDs, the IC metallization is aluminum; in other devices, the IC metallization may be copper. The overcoat is usually made of silicon nitride, commonly 500 to 1000 nm thick. A window 102 is opened in the overcoat in order to expose portion of the IC metallization 103. Not shown in FIG. 1A is the underlayer embedding the metallization.

In FIG. 1A, the dielectric IC portions 104 are only summarily indicated. These electrically insulating portions may include not only the traditional plasma-enhanced chemical vapor deposited dielectrics such as silicon dioxide, but also newer dielectric materials having lower dielectric constants, such as silicon-containing hydrogen silsesquioxane, organic polyimides, aerogels, and parylenes, or stacks of dielectric layers including plasma-generated or ozone tetraethylorthosilicate oxide. Since these materials are less dense and mechanically weaker than the previous standard insulators, the dielectric under the aluminum is often reinforced. Examples can be found in U.S. patent application Ser. No. 90/312,385, filed on May 14, 1999 (Saran et al., “Fine Pitch System and Method for Reinforcing Bond Pads in Semiconductors”), and U.S. Pat. No. 6,232,662, issued May 15, 2001 (Saran, “System and Method for Bonding over Active Integrated Circuits”).

Aluminum is susceptible to oxidation. Consequently, in DMDs with aluminum metallization, the aluminum bond pads, which are exposed to ambient, develop a coherent, although self-limiting aluminum oxide layer. This aluminum oxide layer is harder and more brittle than metallic aluminum, which is relatively soft (Vickers hardness number, VHN, of about 50). During the multiprobe testing step, the tungsten needles of the probe card have to mechanically scratch and pressure through the aluminum oxide layer on the surface in order to contact the underlying metallic aluminum for electrical measurements. The particles of aluminum oxide and aluminum generated by this procedure become easily airborne and create unacceptable problems for the movable micromirrors because the particles get frequently deposited on the mirror surface which are thereafter impeded to remain freely movable. In order to avoid these difficulties, a metal cap is deposited over the aluminum of the bond pad according to the invention. The details of the process, such as aluminum oxide removal prior to cap deposition and the metal deposition itself, are described below.

According to the invention, the cap consists of metal layers, materials and thicknesses such that the cap satisfies four requirements:

The cap should have a hardness high enough to prevent probe needles from gouging the metal, thereby generating particles. Metals of VHN below 70 should not be used. Metals of VHN between 70 and 150 should have a maximum thickness of 0.1 μm to prevent generation of particles 0.1 μm or larger. Metals of VHN between 150 and 300 do not have a maximum thickness limit since particle generation will be minimal. Metals of VHN greater than 300 are able to prevent generation of particles 0.1 μm or larger.

The cap acts as a barrier against the up-diffusion of copper (for copper metallization) to the surface of the cap where it might impede the subsequent wire bonding operation. Specifically, the cap metal selections and thicknesses are coordinated such that the cap reduces the up-diffusion of copper at 250° C. by more than 80% compared with the absence of the barrier metal.

The cap is fabricated by a technique, which avoids expensive photolithographic steps. Specifically, an electroless process is used to deposit at least one of the cap metal layers.

The cap metal has a surface which is selected to be bondable; in other devices, the cap metal surface is selected to be solderable. For the bondable devices, conventional ball and wedge bonding techniques can be used to connect metal wires and other coupling members metallurgically to the bond pad.

For DMDs, wire ball bonding is the preferred method of using coupling members to create electrical connections, as indicated in FIG. 1B. Another method is ribbon bonding employing wedge bonders. In contrast to wedge bonding, ball bonding operates at elevated temperatures for which the materials and processes of this invention need to be harmonized. An alternative method for coupling to other parts is solder bump connection for which the materials and processes of this invention also need to be harmonized.

The wire bonding process begins by positioning both the IC chip with the bond pads and the object, to which the chip is to be bonded, on a heated pedestal to raise their temperature to between 170 and 300° C. A wire 110 (in FIG. 1B), typically of gold, gold-beryllium alloy, other gold alloy, copper, aluminum, or alloys thereof, having a diameter typically ranging from 18 to 33 μm, is strung through a heated capillary where the temperature usually ranges between 200 and 500° C. At the tip of the wire, a free air ball is created using either a flame or a spark technique. The ball has a typical diameter from about 1.2 to 1.6 wire diameters. The capillary is moved towards the chip bonding pad (102 in FIG. 1A) and the ball is pressed against the metallization of the bonding pad (layer 106 in FIGS. 1A and 1B). A combination of compression force and ultrasonic energy creates the formation of a strong metallurgical bond by metal interdiffusion. At time of bonding, the temperature usually ranges from 150 to 270° C. In FIG. 1B, schematic form 111 exemplifies the final shape of the attached “ball” in wire ball bonding. In the first embodiment of the invention, as indicated in FIGS. 1A and 1B, the metal cap over the aluminum (or copper) 103 is provided by two layers:

Layer 105 is positioned over aluminum (or copper) 103, sometimes deposited on a seed metal layer 108. Examples for barrier metals 105 in FIGS. 1A and 1B are nickel, cobalt, chromium, molybdenum, titanium, tungsten, tantalum, palladium, platinum, rhodium, rhenium, osmium, vanadium, iron, ruthenium, niobium, iridium, zirconium, hafnium, copper (for aluminum IC metallization) and alloys thereof. These metals determine the hardness of the cap. The more common of these metals are inexpensive and can be deposited by electroless plating; however, they are poorly bondable.

For IC copper metallization, in these metals, copper has a diffusion coefficient of less than 1·10E−23 cm²/s at 250° C. Consequently, these metals are good copper diffusion barriers. For these metals, the layer thicknesses required to reduce copper diffusion by more than 80% compared to the absence of the layers are obtained by diffusion calculations. Generally, a barrier thickness from about 0.5 to 1.5 μm will safely meet the copper reduction criterion.

Layer 106 is positioned over layer 105 as the outermost layer of the cap; they are bondable, when the device requires wire bonding for assembly, or solderable, when the device requires solder assembly. Examples for layer 106 are gold, platinum, palladium, and silver, rhodium, copper, and alloys thereof. These metals are hard. In addition, these metals have a diffusion coefficient for the metals used in barrier 105 (such as nickel) of less than 1×10E−14 cm²/s at 250° C. Consequently, these metals are good diffusion barriers for the materials of layer 105. Again, the layer thicknesses required to reduce the up-diffusion of metal used in layer 105 by more than 80% compared to the absence of layer 106 are obtained from diffusion calculations. Generally, an outermost layer thickness of 50 to 150 nm will meet the bondability or solderability requirement, and an outermost layer thickness of less than 1.5 μm will safely meet the reduction criterion for metal diffusing from layer 105.

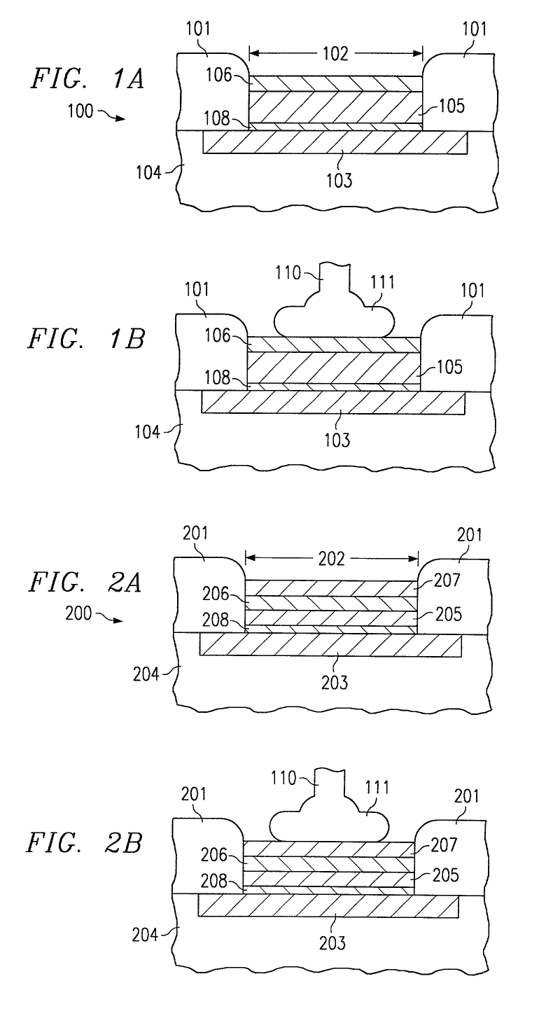

A second embodiment of the invention may provide further cost reduction and hardness improvement for some micromechanical devices. The overall thickness of the bondable metal layer is reduced by a separation into two layers, each selected on their mutual hardness and diffusion characteristics. The second embodiment is generally designated 200 in FIG. 2A; 201 indicates the protective overcoat defining the size 202 of the bond pad. 203 is the aluminum (or copper) metallization of the bond pad, and 204 the underlying dielectric material. The metal cap over the aluminum (or copper) 203 is provided by three layers:

Layer 205 is positioned over aluminum (or copper) area 203, sometimes deposited on a seed metal layer 208. The seed metal may be palladium, 5 to 10 nm thick, or tin. Layer 205 consists of a metal which has sufficient hardness, and also can act as a diffusion barrier against copper for copper-metallized devices. Examples for layer 205 are nickel, cobalt, chromium, molybdenum, titanium, tungsten, and alloys thereof. These metals are inexpensive and can be deposited by electroless plating; however, they are poorly bondable. As mentioned above, in these metals copper has a diffusion coefficient of less than 1×10E−23 cm²/s at 250° C. Consequently, these metals are good copper diffusion barriers. The layer thicknesses, required to reduce copper diffusion by more than 80% compared to the absence of the layers, are obtained by diffusion calculations. Generally, a barrier thickness from about 0.5 to 1.5 μm will safely meet the copper reduction criterion.

Layer 206 is positioned over layer 205 as an additional hard layer and as an effective diffusion barrier against the up-diffusing metal used in layer 205. The intent is to de-emphasize the barrier function of the outermost layer 207, and rather emphasize its bondability function. Consequently, the thickness required for the outermost layer 207 can be reduced, thus saving cost. Examples for layer 206 are palladium, cobalt, platinum, and osmium. Examples for layer 207 are gold, platinum, and silver.

Metals used for layer 206, such as palladium, are hard and have a diffusion coefficient for the metals used in barrier layer 205 (such as nickel) of less than 1×10E−14 cm²/s at 250° C. The layer thicknesses required to reduce the up-diffusion of metal used in layer 205 by more than 80% compared to the absence of layer 206 are obtained from diffusion calculations. Generally, a thickness of layer 206 of about 0.4 to 1.5 μm will safely meet the reduction criterion for metal diffusing from layer 205.

The thickness of the bondable outermost layer 307 (such as gold) can now be reduced to the range of about 0.02 to 0.1 μm.

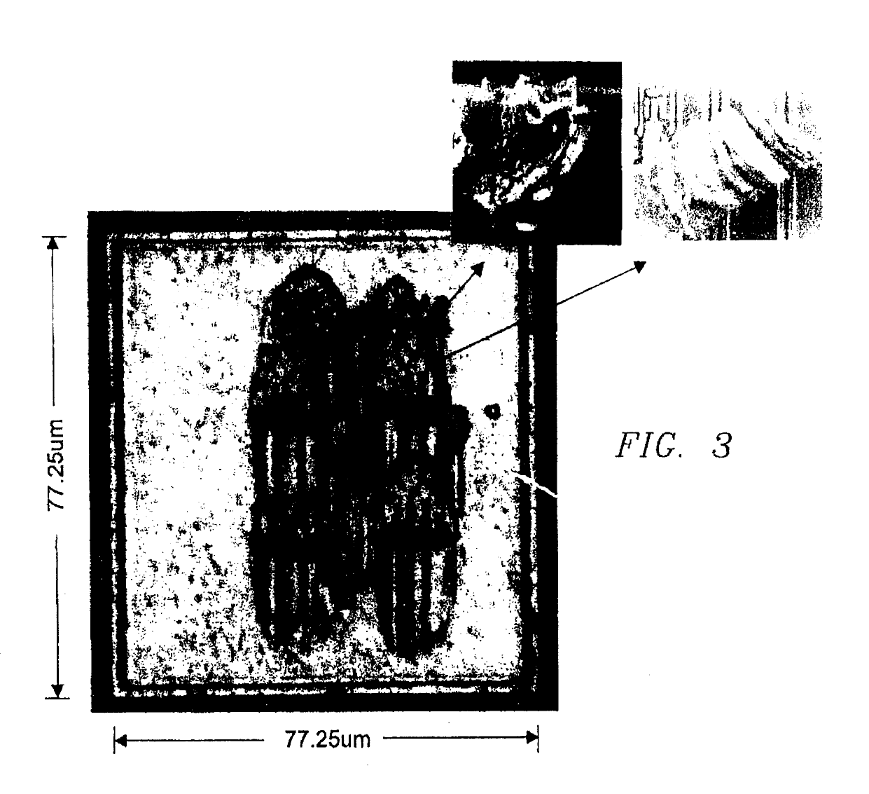

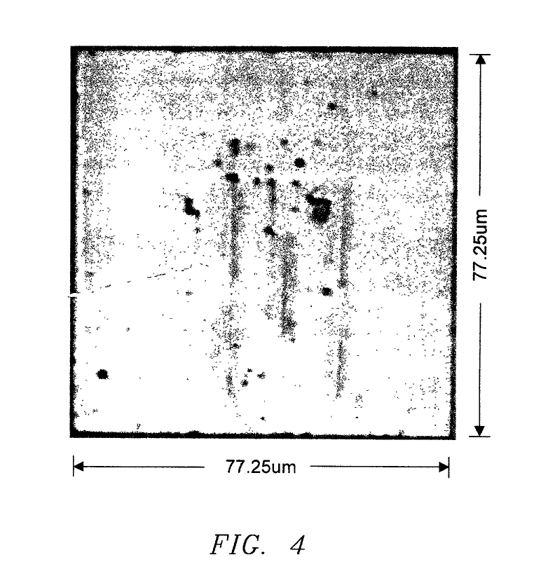

A comparison of the microphotographs of FIG. 3 and FIG. 4 illustrates the success of the cap structure of the invention for eliminating particle generation. FIG. 3 shows a conventional aluminum bond pad after a probe needle has completed 5 touchdowns at 60 μm over-travel, resulting in huge probe mark damage and generation of big particles.

In contrast, FIG. 4 shows the nickel/gold cap over an aluminum bond pad after probe needle has completed 10 touchdowns at 15 μm over-travel, plus 5 touchdowns at 30 μm over-travel, plus 5 touchdowns at 60 μm over-travel, resulting in negligible probe mark damage and no particle generation.

The process steps of depositing the cap barrier and outermost layers can be selected from the techniques of electroless deposition, chemical vapor deposition, deposition by sputtering and deposition by evaporation. Prior to deposition, the process step of removing any oxide layer from the metal surface of the contact terminals or bond pads can be selected from the techniques of sputtering, when the cap metal layers are deposited by chemical vapor deposition, and of cleaning-up in a zincate process, when the cap metal layers are deposited by electroless deposition.

In order to select an example of a fabrication process for the cap metallization of the invention, the low-cost electroless deposition of a three-layer cap will be described for micro-electronic mechanical structures (MEMS), together with the zincate oxide cleaning process.

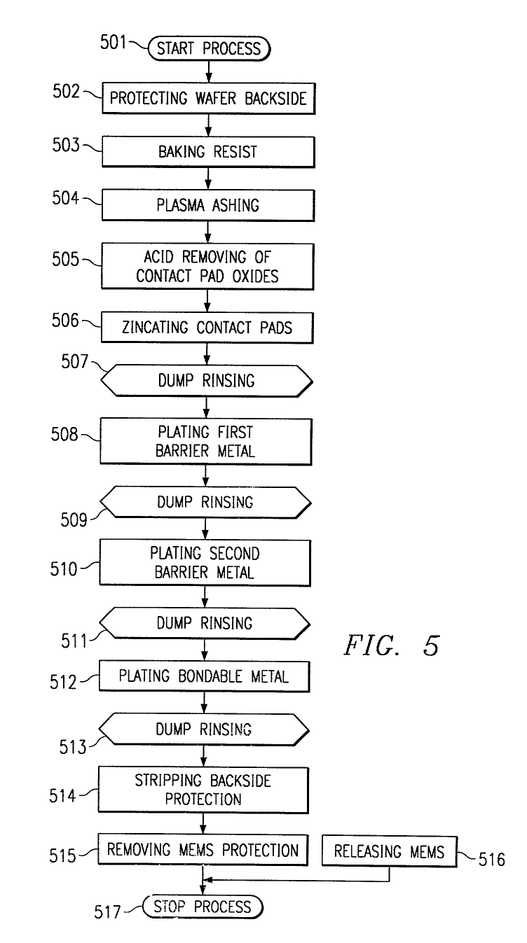

The electroless process used for fabricating the bond pad cap of FIG. 2A is detailed in FIG. 5. After the bond pads have been opened in the protective overcoat, exposing the aluminum IC metallization in bond pad areas, the cap fabrication process starts at 501; the sequence of process steps is as follows:

Step 502: Coating the backside of the silicon IC wafer with resist using a spin-on technique. This coat will prevent accidental metal deposition on the wafer backside.

Step 503: Baking the resist, typically at 110° C. for a time period of about 30 to 60 minutes.

Step 504: Cleaning of the exposed bond pad aluminum surface using a plasma ashing process for about 2 minutes.

Step 505: Removing the aluminum oxide of the contact (bond) pads, in a solution of sulfuric acid, nitric acids, or any other acid, for about 50 to 60 seconds.

Step 506: Zincating the wafer contact pads in acid solution.

Step 507: Rinsing in dump rinser for about 100 to 180 seconds.

Step 508: Electroless plating of first barrier metal. If nickel is selected, plating between 150 to 180 seconds will deposit about 0.4 to 0.6 μm thick nickel.

Step 509: Rinsing in dump rinser for about 100 to 180 seconds.

Step 510: Electroless plating of second barrier metal. If palladium is selected, plating between 150 to 180 seconds will deposit about 0.4 to 0.6 μm thick palladium.

Step 511: Rinsing in dump rinser for about 100 to 180 seconds.

Step 512: Electroless plating of bondable metal. If only thin metal layer is needed, immersion process with self-limiting surface metal replacement is sufficient. If gold is selected, plating between 400 and 450 seconds will deposit approximately 30 nm thick gold. If thicker metal layer (0.5 to 1.5 μm thick) is required, the immersion process is followed by an autocatalytic process step.

Step 513: Rinsing in dump rinser for about 100 to 180 seconds.

Step 514: Stripping wafer backside protection resist for about 8 to 12 minutes.

Step 515: Removing MEMS protection.

Step 516: Releasing MEMS.

The bond pad cap fabrication process stops at 517.

The subsequent metallurgical connection of metal wires or ribbons by a ball or wedge bonding process is described above.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the invention can be applied to IC bond pad metallizations other than aluminum or copper, which are difficult or impossible to bond by conventional ball or wedge bonding techniques, such as alloys of refractory metals and noble metals. As another example, the invention can be extended to batch processing, further reducing fabrication costs. As another example, the invention can be used in hybrid technologies of wire/ribbon bonding and solder interconnections. It is therefore intended that the appended claims encompass any such modifications or embodiments.

We claim:

1. A micromechanical device comprising:
a semiconductor chip having an integrated circuit including a plurality of micromechanical components, and a plurality of conductive routing lines integral with said chip;
said routing lines having contact terminals of oxide-free metal; and
said terminals having a layer of barrier metal on said oxide-free metal and an outermost layer of noble metal, whereby damage-free testing of said circuit is possible using test probe needles.

2. The device according to claim 1 wherein said damage free testing includes a testing process free of particle generation.

3. The device according to claim 1 wherein said micromechanical components are digital mirrors.

4. The device according to claim 1 wherein said routing lines are made of a metal selected from a group consisting of aluminum, aluminum alloy, copper, and copper alloy.

5. The device according to claim 1 wherein said terminals are bond pads or solder pads.

6. The device according to claim 1 wherein said oxide-free metal consists of the metal of said routing line after removal of any metal oxide surface layer.

7. The device according to claim 1 wherein said barrier layer is selected from a group consisting of nickel, cobalt, chromium, molybdenum, titanium, tungsten, tantalum, palladium, platinum, rhodium, rhenium, osmium, vanadium, iron, ruthenium, niobium, iridium, zirconium, hafnium, copper, and alloys thereof in the thickness range from 0.5 to 1.5 μm.

8. The device according to claim 1 wherein said noble metal is a bondable or solderable metal and is selected from a group consisting of gold, platinum, palladium, silver, rhodium, copper and alloys thereof, in the thickness range from about 50 to 150 nm.

9. A method for forming contact terminals suitable for minimum particle generation, said terminals located in routing lines of the semiconductor chip of a micromechanical device, comprising the steps of:
removing any oxide layer from the metal surface of said contact terminals of said routing lines;
activating said metal surface of said terminals, depositing seed metal;
depositing a layer of barrier metal; and
plating an outermost layer of a noble metal.

10. The method according to claim 9 wherein said step of depositing said layer of barrier metal is selected from the techniques of plating by electroless deposition, chemical vapor deposition, deposition by sputtering, and deposition by evaporation.

11. The method according to claim 9 wherein said step of removing said oxide layer is selected from the techniques of sputtering, when said barrier metal layer is deposited by chemical vapor deposition, and of cleaning-up in a zincate process, when said barrier layer is deposited by electroless deposition.
